(19) United States
(12) Patent Application Publication
(10) Pub. No.: US 2013/0264184 A1
(43) Pub. Date: Oct. 10, 2013

(54) CAPACITIVE TOUCH DEVICE

(71) Applicant: Chih-Chung Lin, Taipei City (TW)

(72) Inventor: Chih-Chung Lin, Taipei City (TW)

(21) Appl. No.: 13/759,058

(22) Filed: Feb. 5, 2013

Related U.S. Application Data
(63) Continuation-in-part of application No. 13/442,871, filed on Apr. 10, 2012.

(51) Int. Cl. H03K 17/96

(52) U.S. Cl. CPC H03K 17/962
USPC 200/600

(57) ABSTRACT

A capacitive touch device includes a first transparent substrate, a second transparent substrate and an adhesive layer connecting the first and second transparent substrates with each other. The first transparent substrate has a first side and a second side. A first conductive layer is disposed on the second side. The second transparent substrate has a third side and a fourth side. A second conductive layer is selectively disposed on the third side or the fourth side. The adhesive layer is disposed between the first transparent substrate and the second transparent substrate. By means of the design of the capacitive touch device, the thickness of the touch device is greatly reduced and the manufacturing cost is lowered.

This application is a Continuous-In-Part (CIP) application of U.S. patent application Ser. No. 13/442,871, filed on Apr. 10, 2012.

### BACKGROUND OF THE INVENTION

1. Field of the Invention

The present invention relates generally to a capacitive touch device, and more particularly to a capacitive touch device, which can greatly reduce the thickness of the capacitive touch panel and lower the manufacturing cost.

2. Description of the Related Art

In recent years, following the development of touch panel technique, various portable electronic devices with display function, such as intelligent cellular phones, tablets and MP5, have employed touch panels instead of the conventional mechanical pushbuttons that occupy much room.

In the conventional touch panels, both the single-board touch panel and the double-board touch panel are made of transparent conductive substrates by means of several times of halftone print processes or lithography processes. The transparent conductive substrate is generally made of glass. The unit price of the transparent conductive substrate is quite high. Moreover, in manufacturing, much material is wasted. In case that a defective product is produced in the manufacturing process, it is necessary to discard the entire touch panel without possibility of recovery. This results in waste of cost.

Besides, the lithographic equipment is quite expensive so that the production cost will be inevitably increased as a whole. Moreover, the composition and developer used in the lithography process are both chemical solutions harmful to human bodies. Therefore, the composition and developer used in the lithography process not only will seriously threaten the health of the operators on the scene, but also will lead to serious contamination of ecological environment.

### SUMMARY OF THE INVENTION

A primary object of the present invention is to provide a capacitive touch device, which can lower the manufacturing cost.

A further object of the present invention is to provide the above capacitive touch device, which can greatly reduce the total thickness of the touch device.

To achieve the above and other objects, the capacitive touch device of the present invention includes a first transparent substrate, a second transparent substrate and an adhesive layer. The first transparent substrate has a first side and a second side opposite to the first side. A first conductive layer is disposed on the second side. The second transparent substrate has a third side and a fourth side opposite to the third side. A second conductive layer is selectively disposed on the third side or the fourth side. The adhesive layer is disposed between the first transparent substrate and the second transparent substrate to connect the first and second transparent substrates with each other. By means of the design of the capacitive touch device of the present invention, the thickness of the touch device is greatly reduced and the manufacturing cost is lowered.

Still to achieve the above and other objects, the capacitive touch device of the present includes a first transparent substrate, a second transparent substrate, a touch section, a non-touch section, a shield layer, a first conductive layer, a second conductive layer, a first lead layer, a second lead layer, a flexible circuit board and an adhesive layer. The touch section is disposed at a center of the first transparent substrate and a center of the second transparent substrate. The non-contact section is disposed around the touch section. The first transparent substrate has a first side and a second side opposite to the first side. The shield layer is disposed on a periphery of the second side in the non-contact section. The first conductive layer is disposed on the second side in the touch section and partially extends to the shield layer in the non-contact section. The first lead layer is disposed on the shield layer in the non-contact section in adjacency to the part of the first conductive layer that extends to the shield layer in the non-contact section.

The second transparent substrate has a third side and a fourth side opposite to the third side. The second conductive layer is disposed on the third side in the touch section. A part of the second conductive layer corresponds to the non-contact section. The second lead layer is disposed on the third side in the non-contact section in adjacency to the part of the second conductive layer corresponding to the non-contact section. One end of the flexible circuit board is disposed between the first and second lead layers. A first conductive adhesive layer and a second conductive adhesive layer are respectively disposed between the flexible circuit board and the first lead layer and between the flexible circuit board and the second lead layer. One side of the end of the flexible circuit board is electrically connected to the first lead layer and the first conductive layer via the first conductive adhesive layer. The other side of the end of the flexible circuit board is electrically connected to the second lead layer and the second conductive layer via the second conductive adhesive layer. The adhesive layer is disposed between the first and second transparent substrates to bond the first and second transparent substrates to each other. By means of the design of the capacitive touch device of the present invention, the total thickness of the touch device is greatly reduced. Moreover, the manufacturing cost is greatly lowered.

Still to achieve the above and other objects, the capacitive touch device of the present includes a first transparent substrate, a second transparent substrate, a touch section, a non-touch section, a shield layer, a first conductive layer, a second conductive layer, a first lead layer, a second lead layer, a flexible circuit board and an adhesive layer. The touch section is disposed at a center of the first transparent substrate and a center of the second transparent substrate. The non-contact section is disposed around the touch section. The first transparent substrate has a first side and a second side opposite to the first side. The shield layer is disposed on a periphery of the second side in the non-contact section. The first conductive layer is disposed on the second side in the touch section and partially extends to the shield layer in the non-contact section. The first lead layer is disposed on the shield layer in the non-contact section in adjacency to the part of the first conductive layer that extends to the shield layer in the non-contact section.

The second transparent substrate has a third side and a fourth side opposite to the third side. The second conductive layer is disposed on the fourth side in the touch section. A part of the second conductive layer corresponds to the non-contact section. The second lead layer is disposed on the fourth side in the non-contact section in adjacency to the part of the second conductive layer corresponding to the non-contact section. One end of the flexible circuit board is disposed between the second transparent substrate and the first lead layer. The other end of the flexible circuit board is disposed on the second lead layer. A first conductive adhesive layer and a second conductive adhesive layer are respectively disposed between one end of the flexible circuit board and the first lead layer and the other end of the flexible circuit board and the second lead layer. One end of the flexible circuit board is electrically connected to the first lead layer and the first conductive layer via the first conductive adhesive layer. The other end of the flexible circuit board is electrically connected to the second lead layer and the second conductive layer via the second conductive adhesive layer. The adhesive layer is disposed between the first and second transparent substrates to bond the first and second transparent substrates to each other. By means of the design of the capacitive touch device of the present invention, the total thickness of the touch device is greatly reduced. Moreover, the manufacturing cost is greatly lowered.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a sectional view of a first embodiment of the capacitive touch device of the present invention;

FIG. 2 is a sectional view of a second embodiment of the capacitive touch device of the present invention;

FIG. 3 is a sectional view of a third embodiment of the capacitive touch device of the present invention in one aspect;

FIG. 4 is a sectional view of the third embodiment of the capacitive touch device of the present invention in another aspect;

FIG. 5 is a sectional view of a fourth embodiment of the capacitive touch device of the present invention;

FIG. 6 is a sectional view of a fifth embodiment of the capacitive touch device of the present invention;

FIG. 7 is a sectional view of a sixth embodiment of the capacitive touch device of the present invention in one aspect; and

FIG. 8 is a sectional view of the sixth embodiment of the capacitive touch device of the present invention in another aspect.

### DETAILED DESCRIPTION OF THE PREFERRED EMBODIMENTS

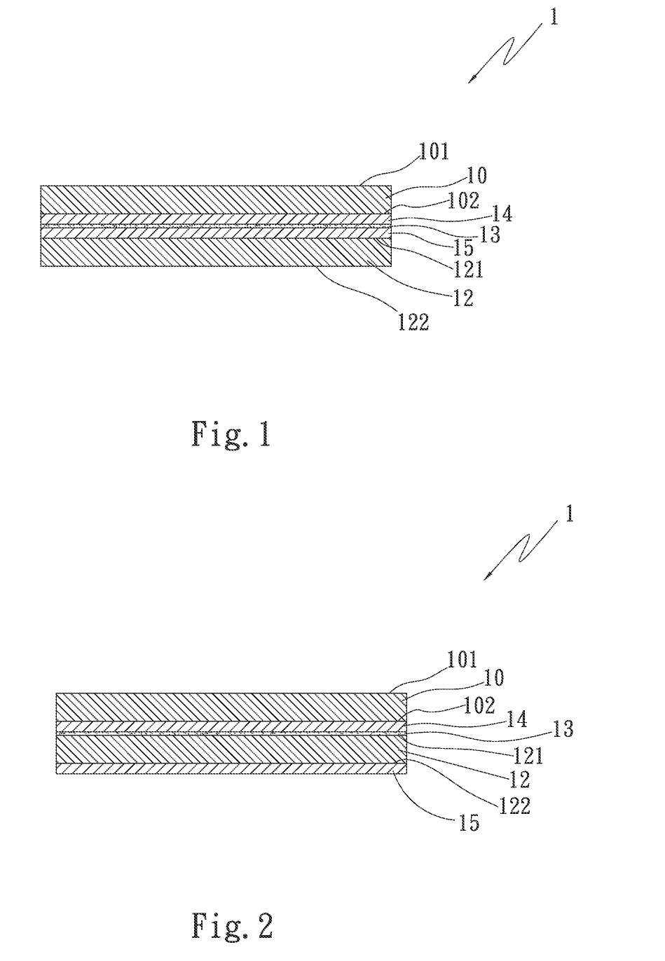

Please refer to FIG. 1, which is a sectional view of a first embodiment of the capacitive touch device of the present invention. According to the first embodiment, the capacitive touch device 1 of the present invention includes a first transparent substrate 10, a second transparent substrate 12 and an adhesive layer 13. The material of the first transparent substrate 10 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the first transparent substrate 10 is, but not limited to, glass for illustration purposes only.

The first transparent substrate 10 has a first side 101 and a second side 102 opposite to the first side 101. A first conductive layer 14 is disposed on the second side 102. The first conductive layer 14 is selected from a group consisting of indium tin oxide (ITO) coating and antimony tin oxide (ATO) coating. The first conductive layer 14 is formed on the second side 102 by means of gelatinization, plating, evaporation or sputtering. In this embodiment, the first conductive layer 14 is formed on the second side 102 by means of, but not limited to, sputtering.

Please further refer to FIG. 1. As the first transparent substrate 10, the material of the second transparent substrate 12 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the second transparent substrate 12 is, but not limited to, glass for illustration purposes only.

The second transparent substrate 12 has a third side 121 and a fourth side 122 opposite to the third side 121. The third side 121 faces the second side 102. A second conductive layer 15 is disposed on the third side 121. As the first conductive layer 14, the second conductive layer 15 is selected from a group consisting of indium tin oxide (ITO) coating and antimony tin oxide (ATO) coating. The second conductive layer 15 is formed on the third side 121 by means of gelatinization, plating, evaporation or sputtering. In this embodiment, the second conductive layer 15 is formed on the third side 121 by means of, but not limited to, sputtering.

The adhesive layer 13 is selected from a group consisting of optical clear adhesive (OCA) and optical clear resin (OCR). The adhesive layer 13 is disposed between the first transparent substrate 10 and the second transparent substrate 12. That is, one side of the adhesive layer 13 is correspondingly adhered to the second conductive layer 15, while the other side of the adhesive layer 13 is correspondingly adhered to the first conductive layer 14. Accordingly, the first and second transparent substrates 10, 12 are integrally connected with each other via the adhesive layer 13.

By means of the design of the capacitive touch device 1 of the present invention, the total thickness of the touch device is greatly reduced. Moreover, the manufacturing cost is greatly lowered.

Please now refer to FIG. 2, which is a sectional view of a second embodiment of the capacitive touch device of the present invention. The second embodiment is substantially identical to the first embodiment in structure, connection relationship and effect and thus will not be repeatedly described hereinafter. The second embodiment is different from the first embodiment in that the second conductive layer 15 is disposed on the fourth side 122 of the second transparent substrate 12 instead of the third side 121. The second conductive layer 15 is formed on the fourth side 122 by means of gelatinization, plating, evaporation or sputtering. In this embodiment, the second conductive layer 15 is formed on the fourth side 122 by means of, but not limited to, sputtering.

One side of the adhesive layer 13 is correspondingly adhered to the third side 121, while the other side of the adhesive layer 13 is correspondingly adhered to the first conductive layer 14. Accordingly, the first and second transparent substrates 10, 12 are integrally connected with each other via the adhesive layer 13. By means of the above arrangement of the capacitive touch device 1 of the present invention, the manufacturing cost is lowered and the total thickness of the touch device is greatly reduced.

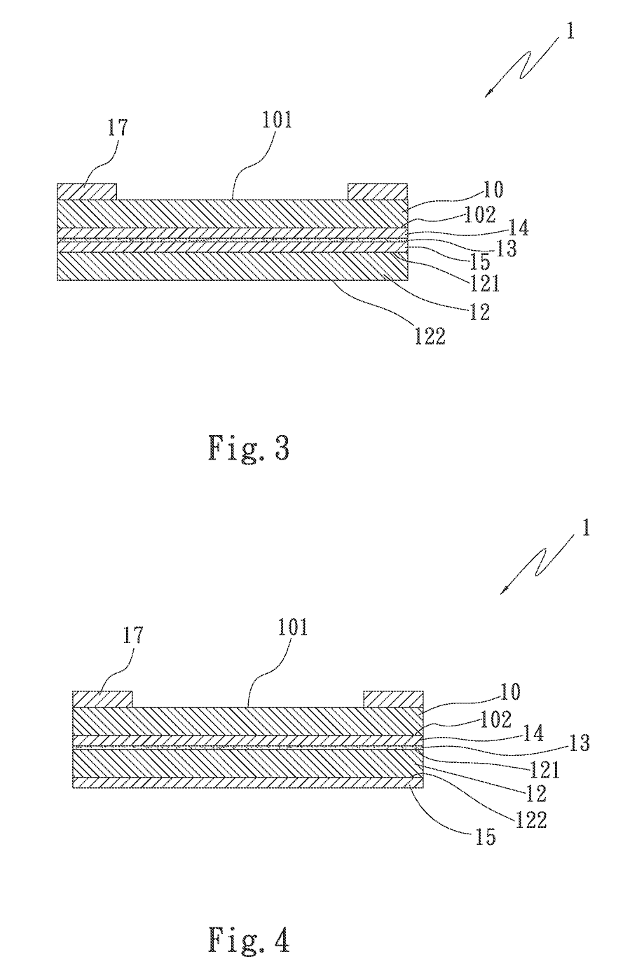

Please now refer to FIGS. 3 and 4. FIG. 3 is a sectional view of a third embodiment of the capacitive touch device of the present invention in one aspect. FIG. 4 is a sectional view of the third embodiment of the capacitive touch device of the present invention in another aspect. The third embodiment is substantially identical to the first and second embodiments in structure, connection relationship and effect and thus will not be repeatedly described hereinafter. The third embodiment is different from the first and second embodiments in that a shield layer 17 is further disposed on the first side 101 of the first transparent substrate 10. The shield layer 17 is disposed on a periphery of the first side 101 to provide shielding and concealing effect. In this embodiment, the shield layer 17 is made of such as a nontransparent insulation material by means of printing or coating.

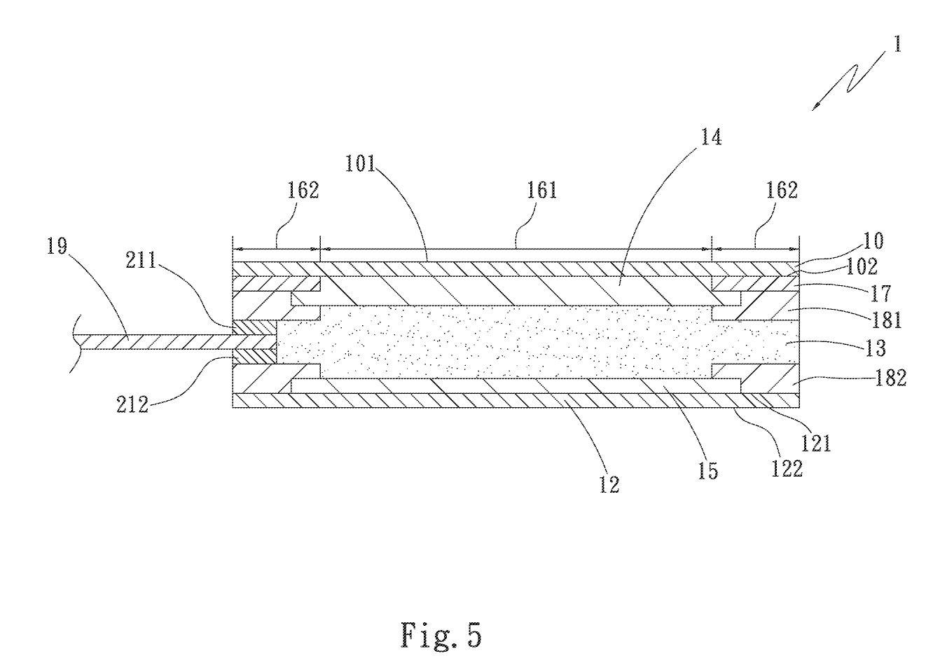

Please now refer to FIG. 5, which is a sectional view of a fourth embodiment of the capacitive touch device of the present invention. The fourth embodiment of the capacitive touch device 1 includes a first transparent substrate 10, a second transparent substrate 12, a touch section 161, a non-touch section 162, a shield layer 17, a first conductive layer 14, a second conductive layer 15, a first lead layer 181, a second lead layer 182, a flexible circuit board 19 and an adhesive layer 13. The material of the first and second transparent substrates 10, 12 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the first and second transparent substrates 10, 12 is, but not limited to, glass for illustration purposes only.

The touch section 161 is disposed at a center of the first transparent substrate 10 and a center of the second transparent substrate 12. The non-contact section 162 is disposed around the touch section 161. The first transparent substrate 10 has a first side 101 and a second side 102 opposite to the first side 101. The shield layer 17 is disposed on a periphery of the second side 102 in the non-contact section for providing shielding and concealing effect. In this embodiment, the shield layer 17 is made of such as a nontransparent insulation material by means of printing or coating.

The first conductive layer 14 is disposed on the second side 102 of the first transparent substrate 10 in the touch section 161 and partially extends to the shield layer 17 in the non-contact section 162. The first conductive layer 14 is selected from a group consisting of indium tin oxide (ITO) coating and antimony tin oxide (ATO) coating. The first conductive layer 14 is formed on the second side 102 by means of gelatinization, plating, evaporation or sputtering. In this embodiment, the first conductive layer 14 is formed on the second side 102 by means of, but not limited to, sputtering.

The first lead layer 181 is disposed on the shield layer 17 in the non-contact section 162 in adjacency to the part of the first conductive layer 14 that extends to the shield layer 17 in the non-contact section 162. The first lead layer 181 is electrically connected to the first lead layer 14. As the first transparent substrate 10, the material of the second transparent substrate 12 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the second transparent substrate 12 is, but not limited to, glass for illustration purposes only.

Further referring to FIG. 5, the second transparent substrate 12 has a third side 121 and a fourth side 122 opposite to the third side 121. The third side 121 faces the second side 102. The second conductive layer 15 is disposed on the third side 121 of the second transparent substrate 12 in the touch section 161. A part of the second conductive layer 15 corresponds to the non-contact section 162. As the first conductive layer 14, the second conductive layer 15 is selected from a group consisting of indium tin oxide (ITO) coating and antimony tin oxide (ATO) coating. The second conductive layer 15 is formed on the third side 121 by means of gelatinization, plating, evaporation or sputtering. In this embodiment, the second conductive layer 15 is formed on the third side 121 by means of, but not limited to, sputtering.

The second lead layer 182 is disposed on the third side 121 in the non-contact section 162 in adjacency to the part of the second conductive layer 15 corresponding to the non-contact section 162. The second lead layer 182 is electrically connected to the second lead layer 15. One end of the flexible circuit board (FPC) 19 is disposed between the first and second lead layers 181, 182 in the non-contact section 162. A first conductive adhesive layer 211 and a second conductive adhesive layer 212 are respectively disposed between the flexible circuit board 19 and the first lead layer 181 and between the flexible circuit board 19 and the second lead layer 182. One side of the first conductive adhesive layer 211 is attached to the first lead layer 181, while the other side of the first conductive adhesive layer 211 is attached to one side of the end of the flexible circuit board 19. Accordingly, one side of the end of the flexible circuit board 19 is electrically connected to the first lead layer 181 and the first conductive layer 14 via the first conductive adhesive layer 211.

In this embodiment, the first and second conductive adhesive layers 211, 212 are, but not limited to, anisotropic conductive films (ACF) for illustration purposes only. In practice, the first and second conductive adhesive layers 211, 212 can be made of any adhesive material that has a vertical electrical conduction but horizontal insulation property and bonding function.

One side of the second conductive adhesive layer 212 is attached to the second lead layer 182, while the other side of the second conductive adhesive layer 212 is attached to the other side of the end of the flexible circuit board 19. Accordingly, the other side of the end of the flexible circuit board 19 is electrically connected to the second lead layer 182 and the second conductive layer 15 via the second conductive adhesive layer 212.

Further referring to FIG. 5, the adhesive layer 13 is selected from a group consisting of optical clear adhesive (OCA) and optical clear resin (OCR). The adhesive layer 13 is disposed between the first and second transparent substrates 10, 12. The adhesive layer 13 is positioned between the first and second conductive layers 14, 15 and between the first and second lead layers 181, 182 to integrally bond (or adhere) the first and second transparent substrates 10, 12 to each other.

By means of the design of the capacitive touch device 1 of the present invention, the total thickness of the touch device is greatly reduced. Moreover, the manufacturing cost is greatly lowered.

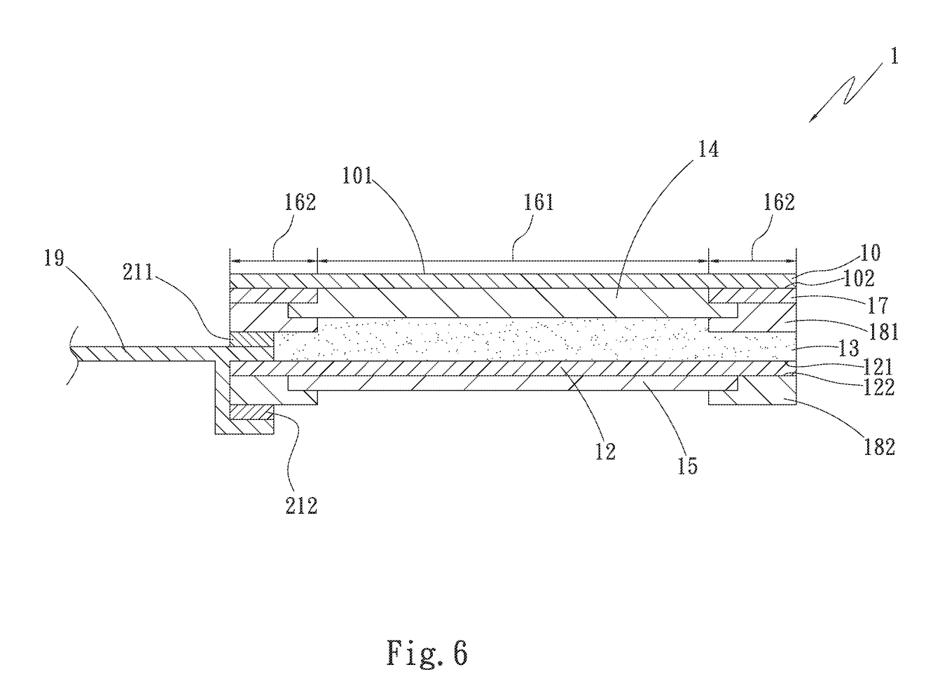

Please now refer to FIG. 6, which is a sectional view of a fifth embodiment of the capacitive touch device of the present invention. The fifth embodiment is substantially identical to the fourth embodiment in structure, connection relationship and effect and thus will not be repeatedly described hereinafter. The fifth embodiment is different from the fourth embodiment in that the second conductive layer 15 is disposed on the fourth side 122 instead of the third side 121. That is, the second conductive layer 15 is disposed on the fourth side 122 of the second transparent substrate 12 in the contact section 161. A part of the second conductive layer 15 corresponds to the non-contact section 162. The second conductive layer 15 is formed on the fourth side 122 by means of gelatinization, plating, evaporation or sputtering. In this embodiment, the second conductive layer 15 is formed on the fourth side 122 by means of, but not limited to, sputtering.

The second lead layer 182 is disposed on the fourth side 122 in the non-contact section 162 in adjacency to the part of the second conductive layer 15 corresponding to the non-contact section 162. The second lead layer 182 is electrically connected to the second lead layer 15. One end of the flexible circuit board (FPC) 19 is disposed between the second transparent substrate 12 and the first lead layer 181 in the non-contact section 162, while the other end of the flexible circuit board 19 is disposed on the second lead layer 182. A first conductive adhesive layer 211 and a second conductive adhesive layer 212 are respectively disposed between one end of the flexible circuit board 19 and the first lead layer 181 and the other end of the flexible circuit board 19 and the second lead layer 182. One side of the first conductive adhesive layer 211 is attached to the first lead layer 181, while the other side of the first conductive adhesive layer 211 is attached to one side of one end of the flexible circuit board 19. The other side of one end of the flexible circuit board 19 is attached to the third side 121 of the second transparent substrate 12. Accordingly, one end of the flexible circuit board 19 is electrically connected to the first lead layer 181 and the first conductive layer 14 via the first conductive adhesive layer 211.

In this embodiment, the first and second conductive adhesive layers 211, 212 are identical to the first and second conductive adhesive layers 211, 212 of the fourth embodiment in material, property and effect and thus will not be repeatedly described.

One side of the second conductive adhesive layer 212 is attached to the second lead layer 182, that is, one side of the second conductive adhesive layer 212 is attached to one side of the second lead layer 182, which side is distal from the fourth side 122 in the non-contact section 162. The other side of the second conductive adhesive layer 212 is attached to the other end of the flexible circuit board 19. Accordingly, the other end of the flexible circuit board 19 is electrically connected to the second lead layer 182 and the second conductive layer 15 via the second conductive adhesive layer 212.

Further referring to FIG. 6, as in the fourth embodiment, the adhesive layer 13 of the fifth embodiment is selected from a group consisting of optical clear adhesive (OCA) and optical clear resin (OCR). The adhesive layer 13 is disposed between the first and second transparent substrates 10, 12. The adhesive layer 13 is positioned between the first conductive layer 14 and the second transparent substrate 12 and between the first lead layer 181 on the first conductive layer 14 and the third side 121 of the second transparent substrate 12 to integrally bond (or adhere) the first and second transparent substrates 10, 12 to each other.

By means of the design of the capacitive touch device 1 of the present invention, the total thickness of the touch device is greatly reduced. Moreover, the manufacturing cost is greatly lowered.

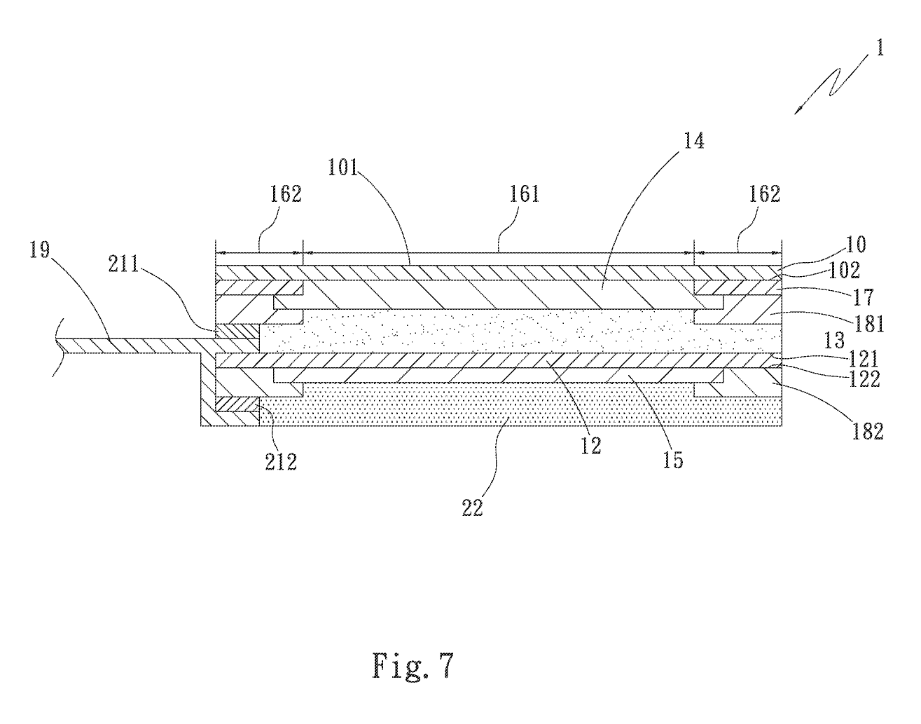

Please now refer to FIG. 7, which is a sectional view of a sixth embodiment of the capacitive touch device of the present invention. The sixth embodiment is substantially identical to the fifth embodiment in structure, connection relationship and effect and thus will not be repeatedly described hereinafter. The sixth embodiment is different from the fifth embodiment in that the sixth embodiment further includes a protection layer 22 disposed on the second conductive layer 15. The protective layer 22 is formed on one side of the second conductive layer 15, which side is distal from the second transparent substrate 12 and on the second lead layer 182 for protecting the second conductive layer 15 and the second lead layer 182.

In this embodiment, the material of the protection layer 22 is, but not limited to, an insulation and non-adhesive material such as polyethylene terephthalate (PET). In practice, the material of the protection layer 22 can be changed according to the environmental and assembling requirements. For example, the material of the protection layer 22 can be selected from a group consisting of optical clear adhesive (OCA) and optical clear resin (OCR) with insulation and adhesive properties.

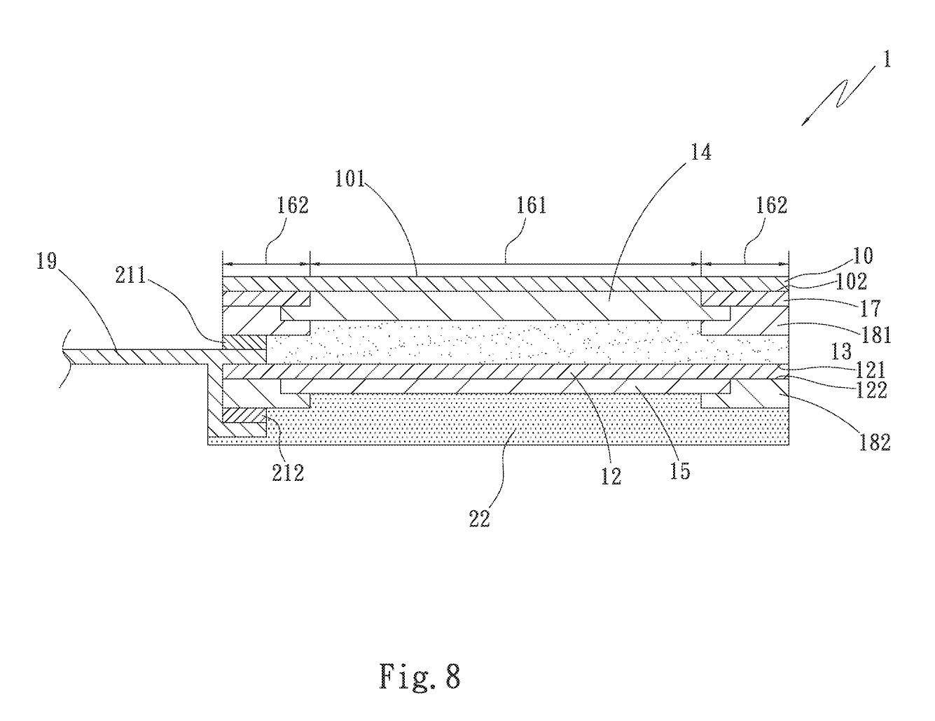

In addition, in practice, the protection layer 22 can extend to cover one side of the other end of the flexible circuit board 19, which side is distal from the second conductive adhesive layer 212 so as to protect the other end of the flexible circuit board 19 (as shown in FIG. 8).

According to the above, in comparison with the conventional touch device, the present invention has the following advantages:

1. The manufacturing cost is lowered.
2. The total thickness of the touch device is greatly reduced.

The above embodiments are only used to illustrate the present invention, not intended to limit the scope thereof. It is understood that many changes and modifications of the above embodiments can be made without departing from the spirit of the present invention. The scope of the present invention is limited only by the appended claims.

What is claimed is:

1. A capacitive touch device comprising:
a first transparent substrate having a first side and a second side opposite to the first side, a first conductive layer being disposed on the second side;
a second transparent substrate having a third side and a fourth side opposite to the third side, a second conductive layer being selectively disposed on the third side or the fourth side; and
an adhesive layer disposed between the first transparent substrate and the second transparent substrate for connecting the first and second transparent substrates with each other.

2. The capacitive touch device as claimed in claim 1, wherein the second conductive layer is formed on the third side, one side of the adhesive layer being correspondingly adhered to the second conductive layer, while the other side of the adhesive layer being correspondingly adhered to the first conductive layer.

3. The capacitive touch device as claimed in claim 1, wherein the second conductive layer is formed on the fourth side, one side of the adhesive layer being correspondingly adhered to the third side, while the other side of the adhesive layer being correspondingly adhered to the first conductive layer.

4. The capacitive touch device as claimed in claim 1, wherein the material of the first and second transparent substrates is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

5. The capacitive touch device as claimed in claim 1, wherein the first and second conductive layers are selected from a group consisting of indium tin oxide (ITO) coatings and antimony tin oxide (ATO) coatings.

6. The capacitive touch device as claimed in claim 2, wherein the first and second conductive layers are respectively formed on the second side and the third side by means of gelatinization, plating, evaporation or sputtering.

7. The capacitive touch device as claimed in claim 3, wherein the first and second conductive layers are respectively formed on the second side and the fourth side by means of gelatinization, plating, evaporation or sputtering.

8. The capacitive touch device as claimed in claim 2, wherein the adhesive layer is selected from a group consisting of optical clear adhesive (OCA) and optical clear resin (OCR).

9. The capacitive touch device as claimed in claim 1, wherein a shield layer is further disposed on the first side of the first transparent substrate, the shield layer being disposed on a periphery of the first side.

10. A capacitive touch device comprising:
a first transparent substrate having a first side and a second side opposite to the first side;
a second transparent substrate having a third side and a fourth side opposite to the third side;
a touch section disposed at a center of the first transparent substrate and a center of the second transparent substrate;
a non-contact section disposed around the touch section;
a shield layer disposed on a periphery of the second side in the non-contact section;
a first conductive layer disposed on the second side in the touch section and partially extending to the shield layer in the non-contact section;
a first lead layer disposed on the shield layer in the non-contact section in adjacency to the part of the first conductive layer that extends to the shield layer in the non-contact section;
a second conductive layer disposed on the third side in the touch section, a part of the second conductive layer corresponding to the non-contact section;
a second lead layer disposed on the third side in the non-contact section in adjacency to the part of the second conductive layer corresponding to the non-contact section;
a flexible circuit board, one end of the flexible circuit board being disposed between the first and second lead layers, a first conductive adhesive layer and a second conductive adhesive layer being respectively disposed between the flexible circuit board and the first lead layer and between the flexible circuit board and the second lead layer, one side of the end of the flexible circuit board being electrically connected to the first lead layer and the first conductive layer via the first conductive adhesive layer, the other side of the end of the flexible circuit board being electrically connected to the second lead layer and the second conductive layer via the second conductive adhesive layer; and
an adhesive layer disposed between the first and second transparent substrates to bond the first and second transparent substrates to each other.

11. The capacitive touch device as claimed in claim 10, wherein the adhesive layer is selected from a group consisting of optical clear adhesive (OCA) and optical clear resin (OCR), the adhesive layer being positioned between the first and second conductive layers and between the first and second lead layers to bond the first and second transparent substrates to each other.

12. The capacitive touch device as claimed in claim 10, wherein the material of the first and second transparent substrates is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

13. The capacitive touch device as claimed in claim 10, wherein the first and second conductive layers are selected from a group consisting of indium tin oxide (ITO) coatings and antimony tin oxide (ATO) coatings.

14. The capacitive touch device as claimed in claim 10, wherein the first and second conductive layers are respectively formed on the second side and the third side by means of gelatinization, plating, evaporation or sputtering.

15. A capacitive touch device comprising:
a first transparent substrate having a first side and a second side opposite to the first side;
a second transparent substrate having a third side and a fourth side opposite to the third side;
a touch section disposed at a center of the first transparent substrate and a center of the second transparent substrate;
a non-contact section disposed around the touch section;
a shield layer disposed on a periphery of the second side in the non-contact section;
a first conductive layer disposed on the second side in the touch section and partially extending to the shield layer in the non-contact section;
a first lead layer disposed on the shield layer in the non-contact section in adjacency to the part of the first conductive layer that extends to the shield layer in the non-contact section;
a second conductive layer disposed on the fourth side in the touch section, a part of the second conductive layer corresponding to the non-contact section;
a second lead layer disposed on the fourth side in the non-contact section in adjacency to the part of the second conductive layer corresponding to the non-contact section;
a flexible circuit board, one end of the flexible circuit board being disposed between the second transparent substrate and the first lead layer, while the other end of the flexible circuit board being disposed on the second lead layer, a first conductive adhesive layer and a second conductive adhesive layer being respectively disposed between one end of the flexible circuit board and the first lead layer and the other end of the flexible circuit board and the second lead layer, one end of the flexible circuit board being electrically connected to the first lead layer and the first conductive layer via the first conductive adhesive layer, while the other end of the flexible circuit board being electrically connected to the second lead layer and the second conductive layer via the second conductive adhesive layer; and
an adhesive layer disposed between the first and second transparent substrates to bond the first and second transparent substrates to each other.

16. The capacitive touch device as claimed in claim 15, wherein the adhesive layer is selected from a group consisting of optical clear adhesive (OCA) and optical clear resin (OCR), the adhesive layer being positioned between the first conductive layer and the second transparent substrate and between the first lead layer on the first conductive layer and the second transparent substrate to bond the first and second transparent substrates to each other.

17. The capacitive touch device as claimed in claim 15, wherein the material of the first and second transparent substrates is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

18. The capacitive touch device as claimed in claim 15, wherein the first and second conductive layers are selected from a group consisting of indium tin oxide (ITO) coatings and antimony tin oxide (ATO) coatings.

19. The capacitive touch device as claimed in claim 15, wherein the first and second conductive layers are respectively formed on the second side and the fourth side by means of gelatinization, plating, evaporation or sputtering.

20. The capacitive touch device as claimed in claim 15, wherein a protection layer is disposed on the second conductive layer, the protective layer being formed on one side of the second conductive layer, which side is distal from the second transparent substrate and on the second lead layer.
